(19) United States
(12) Patent Application Publication
(10) Pub. No.: US 2016/0377460 A1
(43) Pub. Date: Dec. 29, 2016

(54) FAILURE DIAGNOSIS METHOD FOR HALL SENSOR

(71) Applicants: HYUNDAI MOTOR COMPANY, Seoul (KR); KIA MOTORS CORPORATION, Seoul (KR)

(72) Inventors: Sang Lok SONG, Hwaseong-si (KR); Seong Hwan Kim, Hwaseong-si (KR); Hak Sung Lee, Gunpo-si (KR); Gyeong Cheol Kim, Hwaseong-si (KR)

(73) Assignees: HYUNDAI MOTOR COMPANY, Seoul (KR); KIA MOTORS CORPORATION, Seoul (KR)

(21) Appl. No.: 14/933,548

(22) Filed: Nov. 5, 2015

(30) Foreign Application Priority Data
Jun. 29, 2015 (KR) 10-2015-0092335

(51) Int. Cl. G01D 18/00; H02P 6/16; F01M 1/22; G01D 5/14; F01M 1/02

(52) U.S. Cl. CPC G01D 18/00; G01D 5/142; F01M 1/02; F01M 1/22; H02P 6/16; G01R 33/07

(57) ABSTRACT

A failure diagnosis method for a Hall sensor includes: a failure recognizing step of recognizing a failure signal of a Hall sensor by a control unit; a duty increasing step of, when the failure signal is recognized as a result of having performed the failure recognizing step, increasing a driving duty of an oil pump by a preset value; and a failure diagnosing step of diagnosing a failure of the Hall sensor after the duty increasing step.

### CROSS-REFERENCE TO RELATED APPLICATION

The present application claims the benefit of the Korean Patent Application No. 10-2015-0092335, filed Jun. 29, 2015, which is incorporated by reference in its entirety.

### FIELD

The present disclosure relates to a method for diagnosing a failure of a Hall sensor for sensing a location and a rotational direction of a motor.

### BACKGROUND

The statements in this section merely provide background information related to the present disclosure and may not constitute prior art.

In general, a brushless DC (BLDG) motor is applied to an electric oil pump (EOP). The brushless motor has been developed to maintain the characteristics of a three phase DC motor while eliminating a brush for functioning as a commutator in a general three phase DC motor, and includes a rotor having a permanent magnet and a stator on which three coils are wound.

The brushless motor is configured to supply three phase currents to a U phase, a V phase, and a W phase coils wound on the stator, respectively such that the U phase, the V phase, and the W phase coils generate magnetic fields according to the supplied three phase currents, in order to rotate the rotor having a permanent magnet.

Then, in order to precisely control the rotational speed of the rotor of the brushless motor, it is important to precisely estimate the location of the rotor. To achieve this, a Hall sensor is generally used, and the Hall sensor uses a Hall effect and is used to measure the rotational location and direction of the motor. In detail, the Hall sensor may detect a relative location of the rotor to the stator based on the magnetic field generated by the permanent magnet of the rotor.

However, when the Hall sensor fails, a location of the rotor cannot be normally detected. That is, one of the phases of the Hall sensor does not change, and it becomes impossible to control rotation of the motor in a desired way.

If the brushless motor is abnormally operated due to a failure of the Hall sensor, the electric oil pump cannot smoothly form a hydraulic pressure, and accordingly, it is impossible to drive the vehicle. Accordingly, according to the related art, it is diagnosed which of the three phases of the Hall sensor fails based on an output signal of the Hall sensor while the motor is rotated by inertia, when a fail of the Hall sensor is recognized.

However, when the oil temperature of the electric oil pump is low and the RPM thereof is low, a failure of the Hall sensor cannot be smoothly diagnosed because the motor is not smoothly rotated by inertia due to a resistance of the pump and is stopped.

### SUMMARY

The present disclosure provides a failure diagnosis method for a Hall sensor which, when a failure of the Hall sensor is recognized, increases a driving duty of a motor such that the motor maintains an inertial rotation state while a failure of the Hall sensor is diagnosed.

In one aspect, the present disclosure provides a failure diagnosis method for a Hall sensor, including: a failure recognizing step of recognizing a failure signal of a Hall sensor by a control unit; a duty increasing step of, when the failure signal is recognized as a result of having performed the failure recognizing step, increasing a driving duty of an oil pump by a preset value; and a failure diagnosing step of diagnosing a failure of the Hall sensor after the duty increasing step.

The failure signal corresponds to output signals of the three phases of the Hall sensor, all of which are 0 or 1.

In the failure diagnosing step, the control unit diagnoses which of the three phases of the Hall sensor fails.

The failure diagnosis method further includes: a virtual signal calculating step of calculating a virtual signal of the Hall sensor based on the failure diagnosis result such that the oil pump is normally driven; and a virtual signal outputting step of outputting the virtual signal of the Hall sensor to the oil pump.

The control unit is an oil pump unit (OPU), and the oil pump is an electric oil pump (EOP).

According to the failure diagnosis method for a Hall sensor, because a failure of the Hall sensor is diagnosed after the driving duty of the oil pump is increased, a situation in which the oil pump is stopped due to a failure of the Hall sensor and thus it is impossible to diagnose the failure of the Hall sensor and drive the vehicle can be prevented.

In another form, the present disclosure provides a failure diagnosis method for a Hall sensor for a pump, comprising:
receiving output signals from the Hall sensor;
determining by a control unit a failure of the Hall sensor when each of the output signals is 0 or 1;
increasing by the control unit a driving duty of the pump to a predetermined value so as to increase rotational force of a motor of the pump;
diagnosing which of three phases of the Hall sensor fails based on the output signals of the Hall sensor generated through a rotation of the motor.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a view illustrating a failure diagnosis apparatus for a Hall sensor according to one form of the present disclosure; and

FIG. 2 is a flowchart illustrating a failure diagnosis method for a Hall sensor according to one form of the present disclosure.

It should be understood that the appended drawings are not necessarily to scale, presenting a somewhat simplified representation of various features of the present disclosure as disclosed herein, including, for example, specific dimensions, orientations, locations, and shapes will be determined in part by the particular intended application and use environment.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

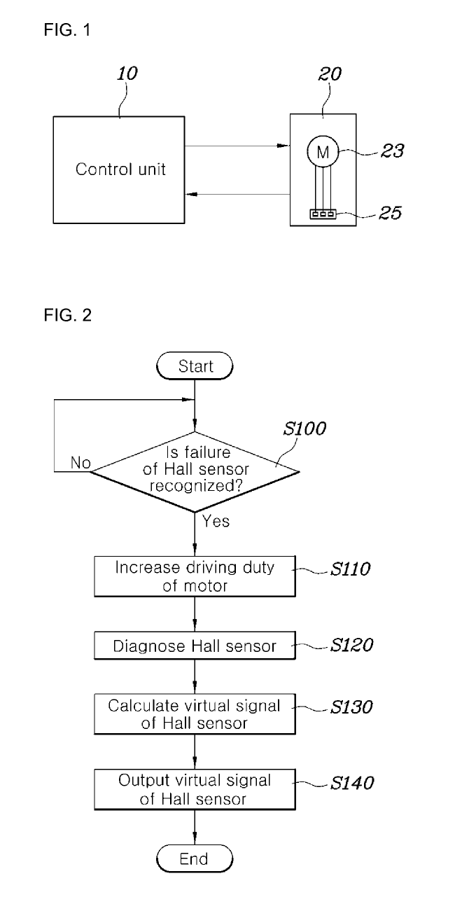

Referring to FIGS. 1 and 2, a failure diagnosis method for a Hall sensor may include: a failure recognizing step S100 of recognizing a failure signal of a Hall sensor 25 by a control unit 10; a duty increasing step S110 of, when the failure signal is recognized as a result of having performed the failure recognizing step, increasing a driving duty of an oil pump 20 by a preset value; and a failure diagnosing step S120 of diagnosing a failure of the Hall sensor 25 after the duty increasing step S110.

Here, the control unit 10 may be an oil pump unit (OPU), and the oil pump 20 may be an electric oil pump (EOP).

The Hall sensor 25 senses a rotational state of a brushless motor 23 to control driving of the oil pump 20, and when at least one of the three phases of the Hall sensor 25 fails, the corresponding failure situation may be smoothly diagnosed.

First, the control unit 10 detects whether a failure signal is output by the Hall sensor 25, and here the failure signal corresponds to output signals of the three-phases of the Hall sensor 25, all of which are 0 or 1. That is, when a motor 23 is rotated, the three-phases of the Hall sensor alternately output output signals of 0 and 1, respectively, according to a predetermined period, and a normal Hall sensor 25 outputs output signals of a three-phase sinusoidal waveform whose PWM electric angle differences are 60°. However, because the failed phase of the three phases of the Hall sensor 25 constantly outputs a signal of 0 or 1, all the three phase output signals are 0 or 1. Accordingly, when output signals all of which are 0 or 1 are received from the Hall sensor 25, the control unit 10 may recognize that the Hall sensor 25 fails.

As described above, when the control unit 10 recognizes a failure situation of the Hall sensor 25, it is necessary to diagnose which of the three phases of the Hall sensor 25 fails but a control to increase a driving duty of the oil pump 20 may be performed beforehand at step S110.

In general, in order to diagnose which of the three phases of the Hall sensor 25 provided in the oil pump 20 fails, it is necessary to maintain the brushless motor 23 of the oil pump 20 in a rotation state by inertia. However, the viscosity of automatic transmission fluid (ATF) increases as the temperature thereof is lowered, and a time period for which the RPM and the inertial rotation of the brushless motor 23 in the oil pump 20 are maintained is reduced.

Accordingly, the control unit 10 increases the driving duty of the oil pump 20 to the preset value to increase the rotational force of the brushless motor 23, so that the inertial rotation of the brushless motor 23 may be maintained in a state where the ATF temperature is low. Accordingly, a situation where it is impossible to diagnose a failure of the Hall sensor 25 due to stop of the rotation of the motor 23 can be prevented by the control unit 10 by securing a time for diagnosing a failure of the Hall sensor 25.

Here, the preset value may be set to be approximately 10%, but may be varied according to the manufacturer, the vehicle, or the driving environment and should not be limited to the exemplary value above.

After the duty increasing step S110, in the failure diagnosing step S120, the control unit 10 diagnoses which of the three phases of the Hall sensor 25 fails.

That is, the brushless motor 23 is rotated by inertia through the duty increasing step S110, and it may be diagnosed which of the three phases of the Hall sensor 25 fails based on the output signals of the Hall sensor 25 generated through the rotation of the motor 23.

Meanwhile, the control unit 10 may further include: a virtual signal calculating step S130 of calculating a virtual signal of the Hall sensor 25 based on the failure diagnosis result through the diagnosing step S120 such that the oil pump 20 is driven in a normal condition; and a virtual signal outputting step S140 of outputting the virtual signal of the Hall sensor 25 to the oil pump 20.

If it is diagnosed which of the three phases of the Hall sensor 25 fails through the failure diagnosing step S120, the control unit 10 can calculate a virtual signal for the failed phase and output the virtual signal to the oil pump 20 such that the oil pump 20 is consistently driven, thereby preventing the driving of the vehicle from being stopped.

According to the failure diagnosis method for a Hall sensor, because a failure of the Hall sensor is diagnosed after the driving duty of the oil pump is increased, a situation in which the oil pump is stopped due to a failure of the Hall sensor and thus it is impossible to diagnose the failure of the Hall sensor and drive the vehicle may be prevented.

The present disclosure has been described in detail with exemplary forms thereof. However, it will be appreciated by those skilled in the art that changes may be made in these forms without departing from the principles and spirit of the present disclosure, the scope of which is defined in the appended claims and their equivalents.

What is claimed is:

1. A failure diagnosis method for a Hall sensor, comprising:
a failure recognizing step of recognizing a failure signal of a Hall sensor by a control unit;
a duty increasing step of increasing a driving duty of an oil pump to a preset value, when the failure signal is recognized through the failure recognizing step; and
a failure diagnosing step of diagnosing a failure of the Hall sensor after the duty increasing step.

2. The failure diagnosis method according to claim 1, wherein the failure signal corresponds to output signals of three phases of the Hall sensor, all of which are 0 or 1.

3. The failure diagnosis method according to claim 1, wherein in the failure diagnosing step, the control unit diagnoses which of three phases of the Hall sensor fails.

4. The failure diagnosis method according to claim 1, further comprising:
a virtual signal calculating step of calculating a virtual signal of the Hall sensor based on a failure diagnosis result through the failure diagnosing step such that the oil pump is normally driven; and
a virtual signal outputting step of outputting the virtual signal of the Hall sensor to the oil pump.

5. The failure diagnosis method according to claim 1, wherein the control unit is an oil pump unit (OPU), and the oil pump is an electric oil pump (EOP).

6. A failure diagnosis method for a Hall sensor for a pump, comprising:
receiving output signals from the Hall sensor;
determining by a control unit a failure of the Hall sensor when each of the output signals is 0 or 1;
increasing by the control unit a driving duty of the pump to a predetermined value so as to increase rotational force of a motor of the pump; and
diagnosing which of three phases of the Hall sensor fails based on the output signals of the Hall sensor generated through a rotation of the motor.
